(19) United States
(12) Patent Application Publication
(10) Pub. No.: US 2014/0208556 A1
(43) Pub. Date: Jul. 31, 2014

(54) JOINING DEVICE AND JOINING SYSTEM

(71) Applicant: Tokyo Electron Limited, Tokyo (JP)

(72) Inventors: Shintaro SUGIHARA, Koshi City (JP); Naoto YOSHITAKA, Koshi City (JP); Shigenori KITAHARA, Koshi City (JP); Keizo HIROSE, Koshi City (JP)

(73) Assignee: TOKYO ELECTRON LIMITED, Tokyo (JP)

(21) Appl. No.: 14/162,990

(22) Filed: Jan. 24, 2014

(30) Foreign Application Priority Data
Jan. 25, 2013 (JP) 2013-012328

(51) Int. Cl. H01L 21/687

(52) U.S. Cl. CPC H01L 21/687
USPC 29/281.1

(57) ABSTRACT

A joining device for joining substrates together includes a first chuck configured to draw and hold a first substrate on a lower surface thereof, a second chuck provided below the first chuck and configured to draw and hold a second substrate on an upper surface thereof, and a chuck holding unit provided below the second chuck, the chuck holding unit including an upper surface and suction grooves annularly formed on the upper surface of the chuck holding unit, the suction grooves configured to vacuum-suck the second chuck to draw and hold the second chuck.

### CROSS-REFERENCE TO RELATED APPLICATION

This application claims the benefit of Japanese Patent Application No. 2013-012328, filed on Jan. 25, 2013, in the Japan Patent Office, the disclosure of which is incorporated herein in its entirety by reference.

### TECHNICAL FIELD

The present disclosure relates to a joining device which joins substrates together and a joining system provided with the joining device.

### BACKGROUND

In recent years, high integration of semiconductor devices has been prompted. However, when a plurality of highly-integrated semiconductor devices is arranged on a horizontal plane and is connected by wiring into a product, the length of the wiring may increase the resistance and make the delay of the wiring large.

Accordingly, the use of a three dimensional integration technology has been proposed which integrates semiconductor devices in three dimensions. In the three dimensional integration technology, for example, a joining system is used to join two semiconductor wafers (hereinafter, referred to as “wafers”) together. For example, the joining system includes a surface hydrophilization device which hydrophilizes the joining surfaces of wafers and a joining device which joins the wafers whose surfaces are hydrophilized by the surface hydrophilization device. In this joining system, the surface hydrophilization device hydrophilizes the surfaces of the wafers by supplying pure water to the surfaces of the wafers. Thereafter, two wafers are disposed in the joining device in a vertically opposing relationship (hereinafter, a wafer positioned at an upper side is referred to as an “upper wafer” and a wafer positioned at a lower side is referred to as a “lower wafer”). The upper wafer drawn and held by an upper chuck and the lower wafer drawn and held by a lower chuck are joined together by the Van der Waals force and by a hydrogen bond (an intermolecular force).

In the lower chuck mentioned above, there is provided, e.g., a chuck holding unit configured to hold the lower chuck. The lower chuck can be horizontally and vertically moved by the chuck holding unit.

The outer periphery portions of the lower chuck and the chuck holding unit of the related art are fixed by screws at a plurality of points. Thus, the screw-fixed sections become singular points. Although the lower chuck and the chuck holding unit make close contact with each other at a plurality of positions in the screw-fixed sections, it is often the case that the lower chuck and the chuck holding unit are vertically distorted in the sections not fixed by screws (in the sections existing between the screws). In this case, the lower wafer held by the lower chuck is also vertically distorted. As a result, when the upper wafer and the lower wafer are joined together, vertical distortion occurs in a joined superposed wafer.

### SUMMARY

Some embodiments of the present disclosure suppress a vertical distortion of a joined superposed substrate by appropriately holding substrates when the substrates are joined together.

According to an embodiment of the present disclosure, provided is a joining device for joining substrates together, including a first chuck configured to draw and hold a first substrate on a lower surface thereof, a second chuck provided below the first chuck and configured to draw and hold a second substrate on an upper surface thereof, and a chuck holding unit provided below the second chuck, the chuck holding unit including an upper surface and suction grooves annularly formed on the upper surface of the chuck holding unit, the suction grooves configured to vacuum-suck the second chuck to draw and hold the second chuck.

According to another embodiment of the present disclosure, provided is a joining system provided with the above-described joining device, the joining system including a processing station including the joining device, and a carry-in/carry-out station configured to retain the first substrate, the second substrate or a superposed substrate obtained by joining the first substrate and the second substrate together, and configured to carry the first substrate, the second substrate or the superposed substrate into and out of the processing station, wherein the processing station includes a surface modification device configured to modify a front surface of the first substrate to be joined or a front surface of the second substrate to be joined, a surface hydrophilization device configured to hydrophilize the front surface of the first substrate or the second substrate modified by the surface modification device, and a transfer zone in which the first substrate, the second substrate or the superposed substrate is transferred with respect to the surface modification device, the surface hydrophilization device and the joining device, wherein the joining device is configured to join the first substrate and the second substrate whose front surfaces are hydrophilized by the surface hydrophilization device.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing a configuration of a joining system according to an embodiment of the present disclosure.

FIG. 2 is a lateral view schematically showing an internal configuration of the joining system according to an embodiment of the present disclosure.

FIG. 3 is a lateral view schematically showing configurations of an upper wafer and a lower wafer.

FIG. 4 is a vertical sectional view schematically showing a configuration of a surface modification device.

FIG. 5 is a plan view of an ion passing structural body.

FIG. 6 is a vertical sectional view schematically showing a configuration of a surface hydrophilization device.

FIG. 7 is a transverse sectional view schematically showing the configuration of the surface hydrophilization device.

FIG. 8 is a transverse sectional view schematically showing a configuration of a joining device.

FIG. 9 is a vertical sectional view schematically showing the configuration of the joining device.

FIG. 10 is a lateral view schematically showing a configuration of a position adjusting mechanism.

FIG. 11 is a plan view schematically showing a configuration of an inverting mechanism.

FIG. 12 is a lateral view schematically showing the configuration of the inverting mechanism.

FIG. 13 is a lateral view schematically showing the configuration of the inverting mechanism.

FIG. 14 is a lateral view schematically showing configurations of a holder arm and a holding member.

FIG. 15 is a vertical sectional view schematically showing configurations of an upper chuck and a lower chuck.

FIG. 16 is a bottom plan view of the upper chuck.

FIG. 17 is a top plan view of the lower chuck.

FIG. 18 is a perspective view showing a lower chuck holding unit.

FIG. 19 is a plan view of the lower chuck holding unit.

FIG. 20 is a flowchart showing main operations of a wafer joining process.

FIG. 21 is an explanatory view showing how to adjust the horizontal positions of the upper wafer and the lower wafer.

FIG. 22 is an explanatory view showing how to adjust the vertical positions of the upper wafer and the lower wafer.

FIG. 23 is an explanatory view showing how the centers of the upper wafer and the lower wafer are brought into contact with each other and pressed together.

FIG. 24 is an explanatory view showing how the upper wafer and the lower wafer are sequentially brought into contact with each other.

FIG. 25 is an explanatory view showing a state in which the surfaces of the upper wafer and the lower wafer are brought into contact with each other.

FIG. 26 is an explanatory view showing a state in which the upper wafer and the lower wafer are joined together.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

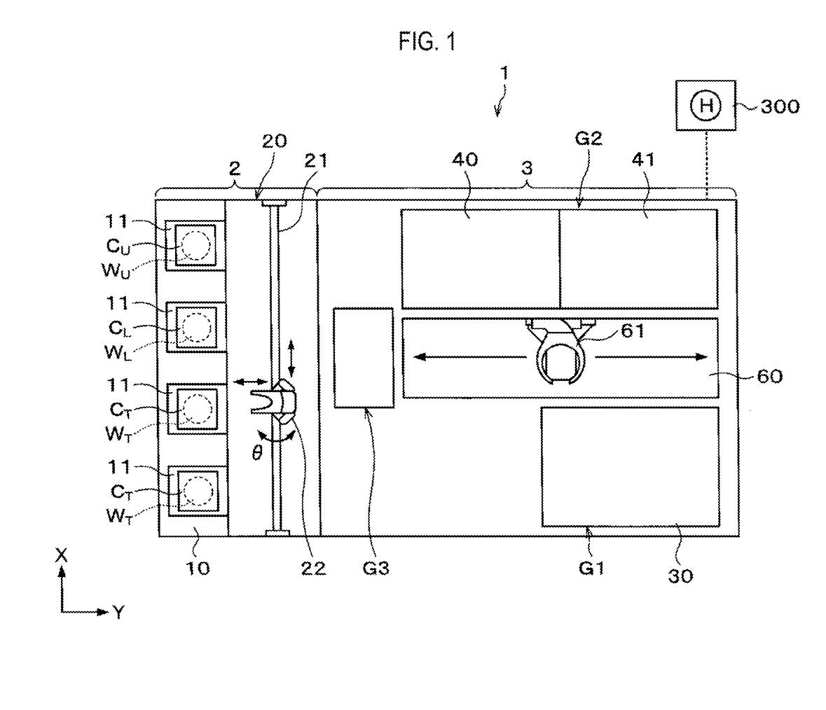

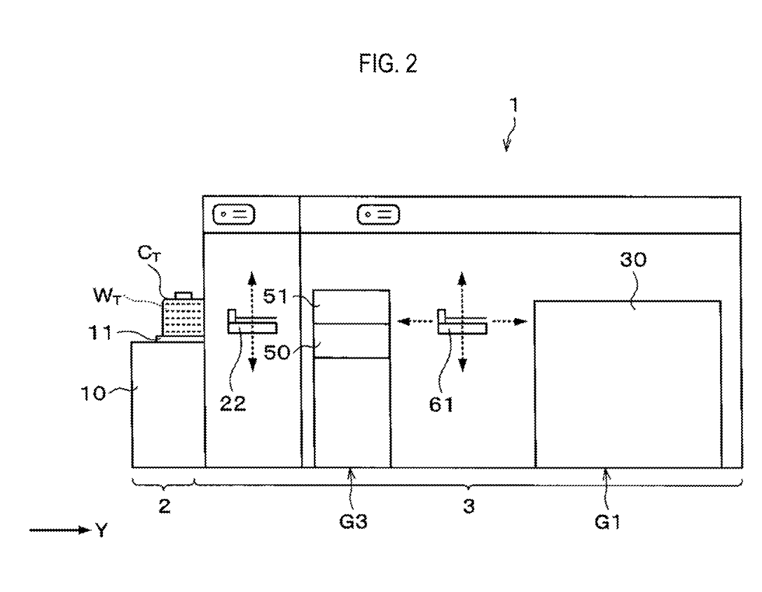

Embodiments of the present disclosure will now be described in detail with reference to the accompanying drawings. FIG. 1 is a schematic plan view showing a configuration of a joining system 1 according to one embodiment. FIG. 2 is a schematic lateral view showing an internal configuration of the joining system 1.

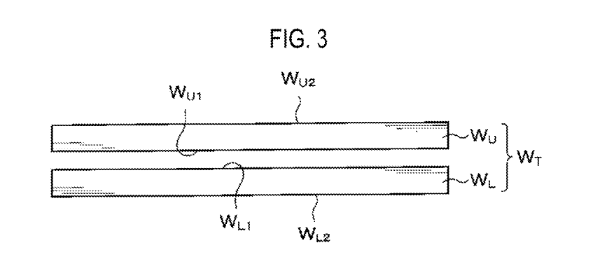

In the joining system 1, for example, two wafers W_{U} and W_{L} as substrates are joined together as shown in FIG. 3. In the following description, a wafer positioned at the upper side will be referred to as an “upper wafer W_{U}” as a first substrate, and a wafer positioned at the lower side will be referred to as a “lower wafer W_{L}” as a second substrate. In the upper wafer W_{U}, a surface that is joined to the lower wafer W_{L} will be referred to as a “front surface W_{U1}”, and an opposite surface of the front surface W_{U1} will be referred to as a “rear surface W_{U2}”. Similarly, in the lower wafer W_{L}, a surface that is joined to the upper wafer W_{U} will be referred to as a “front surface W_{L1}” and an opposite surface of the front surface W_{L1} will be referred to as a “rear surface W_{L2}”. Further, in the joining system 1, a superposed wafer W_{T} as a superposed substrate is obtained by joining the upper wafer W_{U} and the lower wafer W_{L} together.

As shown in FIG. 1, the joining system 1 includes a carry-in/carry-out station 2 in which cassettes C_{U}, C_{L}, and C_{T} are carried in and out of the carry-in/carry-out station 2, and a processing station 3 including various processing units that are configured to perform a predetermined process on the wafers W_{U}, W_{L} and W_{T}, in which the carry-in/carry-out station 2 and the processing station 3 are connected serially. The cassettes C_{U}, C_{L}, and C_{T} are configured to accommodate a plurality of wafers W_{U} and W_{L}, and a plurality of superposed wafers W_{T} therein, respectively.

A cassette mounting stand 10 is disposed in the carry-in/carry-out station 2. A plurality of (e.g., four) cassette mounting boards 11 are mounted on the cassette mounting stand 10. The cassette mounting boards 11 are arranged in a line along an X-axis direction (vertical direction in FIG. 1). The cassette mounting boards 11 can mount thereon the cassettes C_{U}, C_{L} and C_{T}, when they are carried in and out of the joining system 1, respectively. In this way, the carry-in/carry-out station 2 can hold the plurality of upper wafers W_{U}, the plurality of lower wafers W_{L} and the plurality of superposed wafers W_{T}. The number of the cassette mounting boards 11 is not limited to this embodiment but may be designed as appropriate. One of the cassettes may be used as a collection cassette for collecting defective wafers. That is, the collection cassette is provided to receive the defective wafers having a defect generated due to various factors in the joining of the upper wafer W_{U} and the lower wafer W_{L}, except normal superposed wafers W_{T}. In this embodiment, one of the cassettes C_{T} is used as the collection cassette for collecting the defective wafers, and the other cassettes C_{T} are used to receive the normal superposed wafers W_{T}.

In the carry-in/carry-out station 2, a wafer transfer section 20 is disposed adjacent to the cassette mounting stand 10. The wafer transfer section 20 is provided with a wafer transfer unit 22 movable along a transfer path 21 extending in the X-axis direction. The wafer transfer unit 22, which is movable in a vertical direction and is also rotatable about a vertical axis (or in a θ direction), transfers the wafer W_{U}, the wafer W_{L} and the superposed wafer W_{T} between the cassettes C_{U}, C_{L} and C_{T} mounted on the respective cassette mounting boards 11, and transition units 50 and 51 of a third processing block G3 of the processing station 3, which will be described later.

The processing station 3 is provided with a plurality of (e.g., three) processing blocks G1, G2 and G3, which include various processing units. The first processing block G1 is disposed at, e.g., the front side of the processing station 3 in the X-axis direction (at the lower side in FIG. 1). The second processing block G2 is disposed at, e.g., the back side of the processing station 3 in the X-axis direction (at the upper side in FIG. 1). The third processing block G3 is disposed in the vicinity of the carry-in/carry-out station 2 (at the left side of the processing station 3 in a Y-axis direction in FIG. 1).

The first processing block G1 is provided with, e.g., a surface modification device 30 configured to modify the front surfaces W_{U1} and W_{L1} of the wafers W_{U} and W_{L}. In the present embodiment, the surface modification device 30 cuts the bonds of SiO₂ of the front surfaces W_{U1} and W_{L1} of the wafers W_{U} and W_{L} to obtain SiO having a single bond, thereby modifying the front surfaces W_{U1} and W_{L1} so that they can be easily hydrophilized later.

The second processing block G2 is provided with a surface hydrophilization device 40 configured to hydrophilize and clean the front surfaces W_{U1} and W_{L1} of the wafers W_{U} and W_{L} with, e.g., pure water, and a joining device 41 configured to join the wafers W_{U} and W_{L} together, which are arranged in the named order from the carry-in/carry-out station 2 in the Y-axis direction.

The third processing block G3 is provided with the transition units 50 and 51 configured to move the wafers W_{U} and W_{L} and the superposed wafer W_{T}, which are stacked in two stages in order from the bottom to the top, as shown in FIG. 2.

As shown in FIG. 1, an area which is bounded by the first to third processing blocks G1 to G3 is defined as a wafer transfer zone 60. For example, a wafer transfer unit 61 is disposed in the wafer transfer zone 60.

The wafer transfer unit 61 is equipped with a transfer arm (not shown) which is movable in the vertical and horizontal directions (the X and Y-axis directions) and is rotatable about a vertical axis. The wafer transfer unit 61 moves inside the wafer transfer zone 60 so that the wafers W_{U} and W_{L} and the superposed wafer W_{T} can be transferred to specified units installed in the first to third processing blocks G1, G2 and G3.

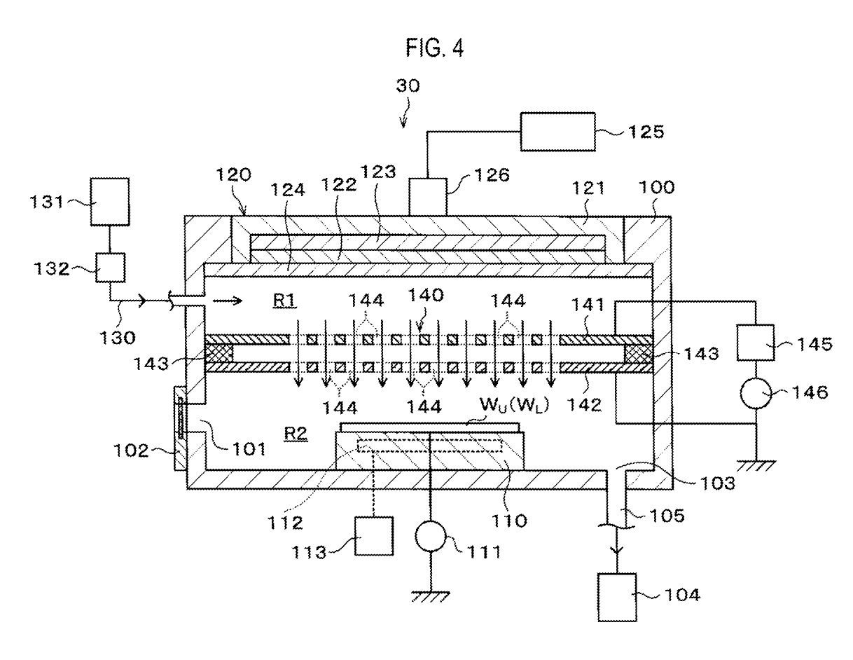

Next, a configuration of the abovementioned surface modification device 30 will be described. As shown in FIG. 4, the surface modification device 30 includes a processing vessel 100. The processing vessel 100 has an upper surface opening in which a radial line slot antenna 120 to be described later is arranged. The processing vessel 100 is configured such that the interior thereof can be hermetically sealed.

An inlet/outlet 101 through which the wafers W_{U} and W_{L} are transferred is formed on the side surface of the side of the processing vessel 100 facing the wafer transfer zone 60. A gate valve 102 is provided at the inlet/outlet 101.

A suction port 103 is formed on the bottom surface of the processing vessel 100. A suction pipe 105 communicating with a suction unit 104 for depressurizing the internal atmosphere of the processing vessel 100 to a predetermined vacuum degree is connected to the suction port 103.

A mounting table 110 for mounting the wafers W_{U} and W_{L} thereon is provided on the bottom surface of the processing vessel 100. The mounting table 110 can mount the wafers W_{U} and W_{L} thereon by, e.g., electrostatic drawing or vacuum suction. An ion ammeter 111 configured to measure an ion current generated by ions (oxygen ions) of a process gas irradiated toward the wafers W_{U} and W_{L} mounted on the mounting table 110 in the below-mentioned manner is installed in the mounting table 110.

A temperature adjusting mechanism 112 configured to allow, e.g., a cooling medium, to flow therethrough is installed within the mounting table 110. The temperature adjusting mechanism 112 is connected to a liquid temperature adjusting unit 113 which serves to adjust the temperature of the cooling medium. The temperature of the cooling medium is adjusted by the liquid temperature adjusting unit 113, which makes it possible to control the temperature of the mounting table 110. As a result, the wafers W_{U} and W_{L} mounted on the mounting table 110 can be kept at a predetermined temperature.

Lift pins (not shown) for supporting the wafers W_{U} and W_{L} from below and moving the wafers WU and WL up and down are provided below the mounting table 110. The lift pins are inserted into through-holes (not shown) formed in the mounting table 110 and can protrude from the upper surface of the mounting table 110.

A radial line slot antenna 120 configured to supply plasma-generating microwaves is provided in the upper surface opening of the processing vessel 100. The radial line slot antenna 120 includes an antenna body 121 which has a lower surface opening. A flow path (not shown) configured to allow, e.g., a cooling medium, to flow therethrough is provided within the antenna body 121.

A slot plate 122 having a plurality of slots and serving as an antenna is provided in the lower surface opening of the antenna body 121. An electrically conductive material, e.g., copper, aluminum or nickel, is used as the material of the slot plate 122. A lagging plate 123 is provided above the slot plate 122 within the antenna body 121. A low-loss dielectric material, e.g., quartz, alumina or aluminum nitride, is used as the material of the lagging plate 123.

A microwave-transmitting plate 124 is provided below the antenna body 121 and the slot plate 122. The microwave-transmitting plate 124 is arranged through a seal material (not shown), e.g., an O-ring, to close the interior of the processing vessel 100. A dielectric material, e.g., quartz or Al₂O₃, is used as the material of the microwave-transmitting plate 124.

A coaxial waveguide pipe 126 communicating with a microwave generating unit 125 is connected to the upper portion of the antenna body 121. The microwave generating unit 125 is provided outside the processing vessel 100 and can supply microwaves of predetermined frequency, e.g., 2.45 GHz, to the radial line slot antenna 120.

With this configuration, the microwaves generated from the microwave generating unit 125 are propagated into the radial line slot antenna 120 and are compressed by the lagging plate 123 to have a short wavelength, thereby generating circularly polarized waves in the slot plate 122, which, in turn, are transmitted through the microwave-transmitting plate 124 and irradiated toward the interior of the processing vessel 100.

A gas supply pipe 130 configured to supply an oxygen gas as a process gas into the processing vessel 100 is connected to the side surface of the processing vessel 100. The gas supply pipe 130 is arranged above an ion passing structural body 140 to be described later and is configured to supply an oxygen gas to a plasma generation region R1 defined within the processing vessel 100. The gas supply pipe 130 communicates with a gas supply source 131 which retains an oxygen gas therein. A supply kit 132 including a valve, a flow rate adjusting unit or the like, which control the flow of an oxygen gas, is provided in the gas supply pipe 130.

An ion passing structural body 140 is provided between the mounting table 110 within the processing vessel 100 and the radial line slot antenna 120. That is, the ion passing structural body 140 is provided to divide the interior of the processing vessel 100 into a plasma generation region R1 in which the oxygen gas supplied from the gas supply pipe 130 is turned to plasma by the microwaves irradiated from the radial line slot antenna 120 and a processing region R2 in which the front surfaces W_{U1} and W_{L1} of the wafers W_{U} and W_{L} mounted on the mounting table 110 are modified by oxygen ions generated in the plasma generation region R1.

The ion passing structural body 140 includes a pair of electrodes 141 and 142. In the following description, the electrode disposed at the upper side will be sometimes referred to as an “upper electrode 141” and the electrode disposed at the lower side will be sometimes referred to as a “lower electrode 142”. An insulating material 143 configured to electrically insulate the electrodes 141 and 142 from each other is provided between the electrodes 141 and 142.

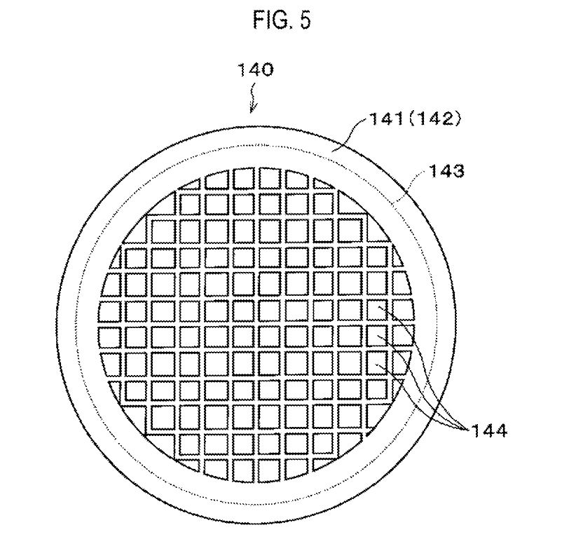

As shown in FIGS. 4 and 5, the respective electrodes 141 and 142 has a circular shape when seen in a plan view and has a diameter larger than the diameter of the wafers W_{U} and W_{L}. Each of the electrodes 141 and 142 has a plurality of openings 144 through which oxygen ions move from the plasma generation region R1 to the processing region R2. The openings 144 are arranged, e.g., in a lattice pattern. The shape and arrangement of the openings 144 are not limited to those of the present embodiment but may be arbitrarily set.

In some embodiments, the dimension of each of the openings 144 is set, e.g., smaller than the wavelength of the microwaves irradiated from the radial line slot antenna 120. This ensures that the microwaves supplied from the radial line slot antenna 120 are reflected by the ion passing structural body 140 and are restrained from entering the processing region R2. As a consequence, the wafers W_{U} and W_{L} mounted on the mounting table 110 are not directly exposed to the microwaves. This makes it possible to prevent the wafers W_{U} and W_{L} from being damaged by the microwaves.

A power supply 145 configured to apply a predetermined voltage between the electrodes 141 and 142 is connected to the ion passing structural body 140. The predetermined voltage applied by the power supply 145 is controlled by a control unit 300 to be described later. The maximum voltage applied by the power supply 145 is, e.g., 1 KeV. An ammeter 146 configured to measure the electric current flowing between the electrodes 141 and 142 is connected to the ion passing structural body 140.

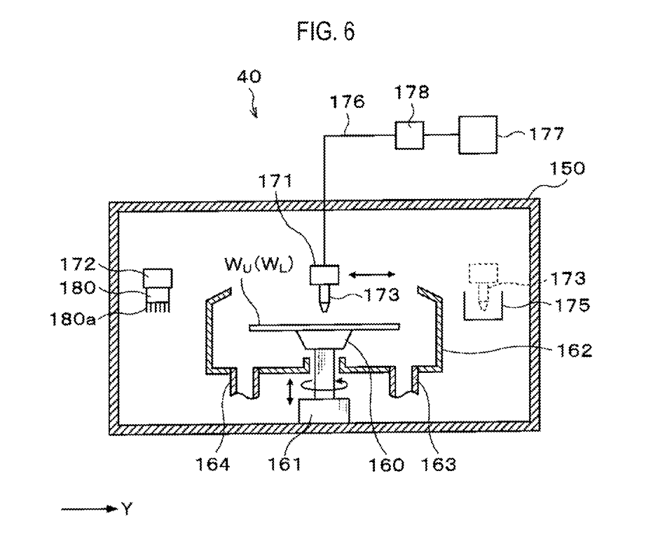

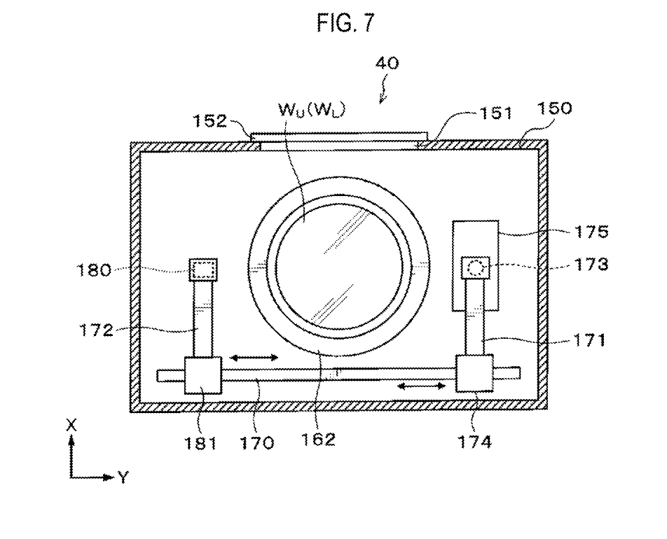

Next, a configuration of the aforementioned surface hydrophilization device 40 will be described. As shown in FIG. 6, the surface hydrophilization device 40 includes a processing vessel 150, the interior of which is sealable. As shown in FIG. 7, an inlet/outlet 151 through which the wafer W_{U} (or W_{L}) is transferred is formed at a lateral side of the processing vessel 150 facing the wafer transfer zone 60. An opening/closing shutter 152 is disposed in the inlet/outlet 151.

As shown in FIG. 6, a spin chuck 160 configured to hold and rotate the wafer W_{U} (or W_{L}) is disposed in a central portion inside the processing vessel 150. The spin chuck 160 includes a horizontal upper surface on which, e.g., suction holes (not shown) for sucking the wafer W_{U} (or W_{L}) are formed. Using the suction force of the suction holes, the spin chuck 160 can suck and hold the wafer W_{U} (or W_{L}).

A chuck drive unit 161 equipped with, e.g., a motor, is installed below the spin chuck 160. The spin chuck 160 can be rotated at a predetermined speed by the chuck drive unit 161. The chuck drive unit 161 is provided with an up-down drive source (not shown) such as a cylinder or the like and can move the spin chuck 160 up and down.

A cup 162 is provided around the spin chuck 160 to receive and collect liquid dropped or scattered from the wafer W_{U} (or W_{L}). A discharge pipe 163 configured to drain the collected liquid and an exhaust pipe 164 configured to vacuum-suck and discharge an atmosphere within the cup 162 are connected to the bottom surface of the cup 162.

As shown in FIG. 7, a rail 170 extending in the Y-axis direction (the left-right direction in FIG. 7) is formed at the back side of the cup 162 in the X-axis direction (at the lower side in FIG. 7). The rail 170 is formed at the outer side of the cup 162 to extend, e.g., from the back side (the left side in FIG. 7) to the front side (the right side in FIG. 7) of the cup 162 in the Y-axis direction. A nozzle arm 171 and a scrub arm 172 are mounted in the rail 170.

As shown in FIGS. 6 and 7, the nozzle arm 171 supports a pure water nozzle 173 configured to supply pure water to the wafer W_{U} (or W_{L}). As shown in FIG. 7, the nozzle arm 171 is movable along the rail 170 by a nozzle drive unit 174. With this configuration, the pure water nozzle 173 is movable from a standby section 175 provided at the front outer side of the cup 162 in the Y-axis direction up to above the central portion of the wafer W_{U} (or W_{L}) positioned within the cup 162, and also is movable above the wafer W_{U} (or W_{L}) in the diameter direction of the wafer W_{U} (or W_{L}). The nozzle arm 171 is movable up and down by operating the nozzle drive unit 174 to adjust the height of the pure water nozzle 173.

As shown in FIG. 6, the pure water nozzle 173 is connected to a supply pipe 176 configured to supply the pure water to the pure water nozzle 173. The supply pipe 176 communicates with a pure water supply source 177 which retains the pure water therein. Further, a supply kit 178 including a valve, a flow rate regulator or the like, which controls a flow of the pure water, is installed in the supply pipe 176.

The scrub arm 172 supports a scrub cleaning tool 180. For example, a plurality of brushes 180a having a string-like shape or a sponge-like shape is formed at a tip end of the scrub cleaning tool 180. The scrub arm 172 is movable along the rail 170 by operating a cleaning tool drive unit 181 shown in FIG. 7. With this configuration, the scrub cleaning tool 180 is movable from the rear outer side of the cup 162 in the Y-axis direction up to above the central portion of the wafer W_{U} (or W_{L}) positioned within the cup 162. Further, the scrub arm 172 is moved up and down by the cleaning tool drive unit 181 to adjust the height of the scrub cleaning tool 180.

In the above configuration, the pure water nozzle 173 and the scrub cleaning tool 180 are supported by different arms. However, the pure water nozzle 173 and the scrub cleaning tool 180 may be supported by a single arm. In one embodiment, the pure water may be supplied from the scrub cleaning tool 180 without the pure water nozzle 173. In some embodiments, a discharge pipe configured to discharge the liquid and an exhaust pipe configured to exhaust the internal atmosphere of the processing vessel 150 may be connected to the bottom surface of the processing vessel 150, without the cup 162. In some embodiments, the surface hydrophilization device 40 configured as above may include an antistatic ionizer (not shown).

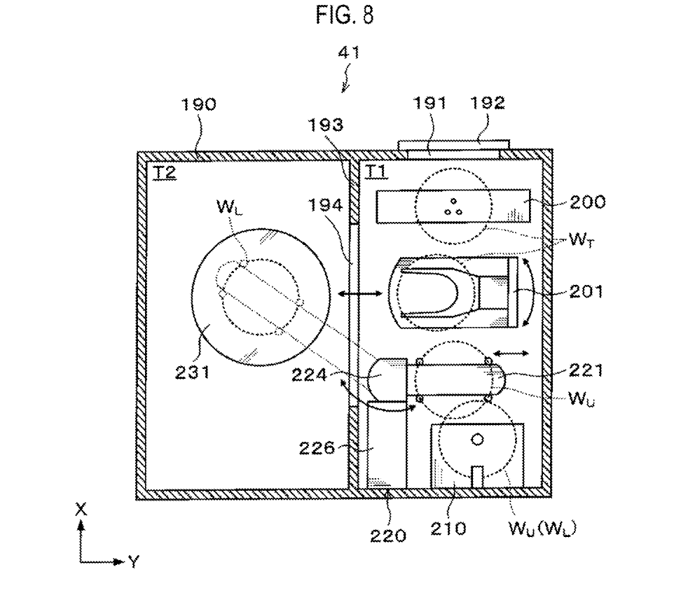

Next, a configuration of the abovementioned joining device 41 will be described. As shown in FIG. 8, the joining device 41 includes a processing vessel 190, the interior of which is sealable. An inlet/outlet 191, through which the wafer W_{U} (or W_{L}) and the superposed wafer W_{T} are transferred, is formed at a lateral side of the processing vessel 190 facing the wafer transfer zone 60. An opening/closing shutter 192 is provided in the inlet/outlet 191.

The interior of the processing vessel 190 is partitioned into a transfer region T1 and a processing region T2 by an internal wall 193. The inlet/outlet 191 mentioned above is formed in a lateral side of the processing vessel 190 facing the wafer transfer zone 60 in the transfer region T1. Further, an inlet/outlet 194, through which the wafer W_{U} (or W_{L}) and the superposed wafer W_{T} are transferred, is formed in the internal wall 193.

A transition 200, on which the wafer W_{U} (or W_{L}) and the superposed wafer W_{T} are temporarily mounted, is formed at the forward side (the top side in FIG. 8) of the transfer region T1 in the X-axis direction. The transition 200 is formed in, e.g., two stages, to simultaneously mount any two of the wafers W_{U} and W_{L} and the superposed wafer W_{T} thereon.

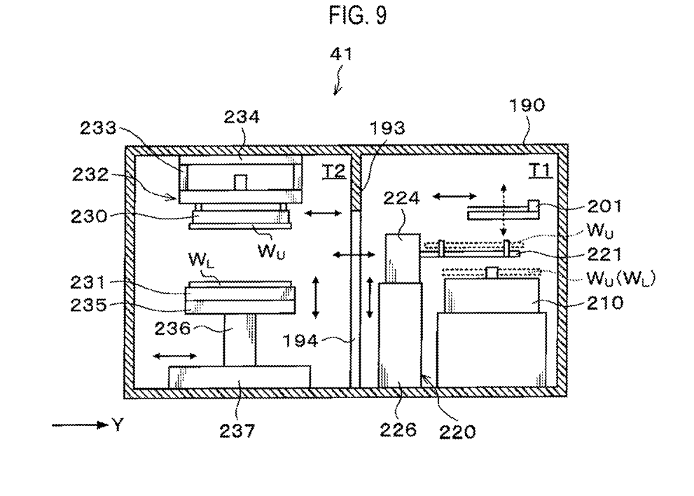

A wafer transfer mechanism 201 is installed in the transfer region T1. As shown in FIGS. 8 and 9, the wafer transfer mechanism 201 includes, e.g., a transfer arm which is movable in the vertical and horizontal directions (the Y- and X-directions) and which is rotatable about a vertical axis. The wafer transfer mechanism 201 can transfer the wafer W_{U} (or W_{L}) and the superposed wafer W_{T} within the transfer region T1 or between the transfer region T1 and the processing region T2.

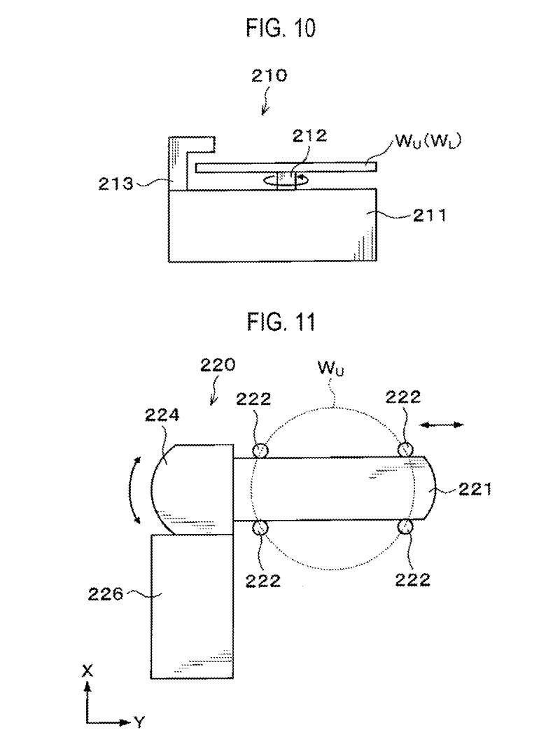

A position adjusting mechanism 210 configured to adjust a horizontal orientation of the wafer W_{U} (or W_{L}) is disposed at the back side of the transfer region T1 in the X-axis direction. As shown in FIG. 10, the position adjusting mechanism 210 is equipped with a base table 211, a holding unit 212 configured to draw, hold and rotate the wafer W_{U} (or W_{L}), and a detection unit 213 configured to detect a position of a notch portion formed in the wafer W_{U} (or W_{L}). In the position adjusting mechanism 210, the detection unit 213 detects the position of the notch portion of the wafer W_{U} (or W_{L}), while rotating the wafer W_{U} (or W_{L}) drawn and held by the holding unit 212 such that the position of the notch portion is adjusted. Thus, the position adjusting mechanism 210 adjusts the horizontal orientation of the wafer W_{U} (or W_{L}).

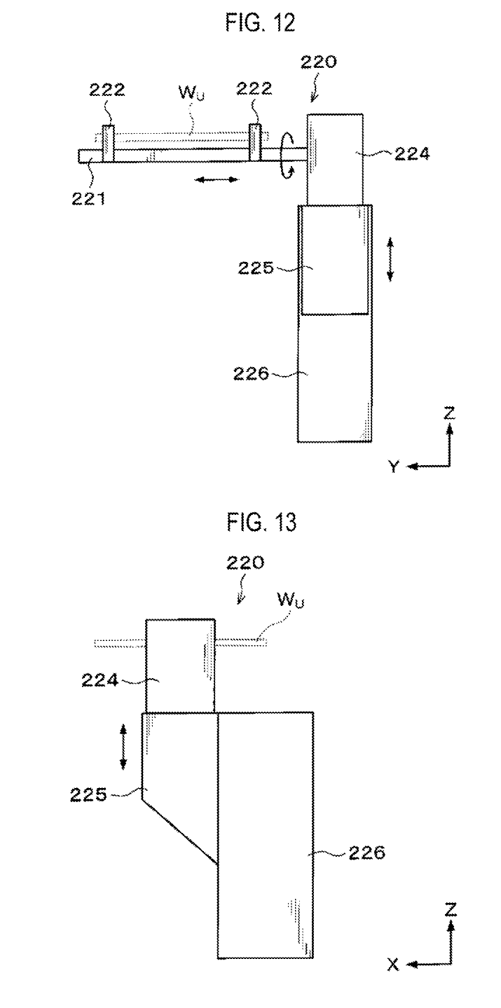

An inverting mechanism 220 configured to invert the front and rear surfaces of the upper wafer W_{U} is installed in the transfer region T1. As shown in FIGS. 11 to 13, the inverting mechanism 220 includes a holder arm 221 configured to hold the upper wafer W_{U}. The holder arm 221 extends in the horizontal direction (the Y-direction in FIGS. 11 and 12). Holding members 222 configured to hold the upper wafer W_{U} are installed at, e.g., four points, in the holder arm 221. As shown in FIG. 14, the holding members 222 are configured such that they can be horizontally moved with respect to the holder arm 221. Cutouts 223 for holding the outer peripheral portion of the upper wafer W_{U} are formed on the side surfaces of the holding members 222. The holding members 222 can hold the upper wafer W_{U} interposed therebetween.

As shown in FIGS. 11 to 13, the holder arm 221 is supported by a first drive unit 224 which includes, e.g., a motor. The holder arm 221 can be rotated about a horizontal axis by the first drive unit 224. The holder arm 221 is not only rotatable about the first drive unit 224 but also movable in the horizontal direction (the Y-direction in FIGS. 11 and 12). A second drive unit 225 including, e.g., a motor, is provided below the first drive unit 224. The first drive unit 224 can be vertically moved by the second drive unit 225 along a support post 226 extending in the vertical direction. In this way, the upper wafer W_{U} held by the holding members 222 can be rotated about a horizontal axis and can be vertically and horizontally moved by the first drive unit 224 and the second drive unit 225. The upper wafer W_{U} held by the holding members 222 can rotate about the first drive unit 224 and can move between the position adjusting mechanism 210 and an upper chuck 230 to be described below.

As shown in FIGS. 8 and 9, an upper chuck 230 as a first chuck configured to draw and hold the upper wafer W_{U} on the lower surface thereof and a lower chuck 231 as a second chuck configured to mount, draw and hold the lower wafer W_{L} on the upper surface thereof are provided in the processing region T2. The lower chuck 231 is disposed below the upper chuck 230 and is configured to face the upper chuck 230. That is, the upper wafer W_{U} held by the upper chuck 230 and the lower wafer W_{L} held by the lower chuck 231 can be arranged opposite to each other.

As shown in FIG. 9, the upper chuck 230 is held by an upper chuck holding unit 232. An upper chuck drive unit 234 is installed above the upper chuck holding unit 232 through support posts 233. The upper chuck 230 can be horizontally moved by the upper chuck drive unit 234.

The lower chuck 231 is held by a lower chuck holding unit 235. A lower chuck drive unit 237 is installed below the lower chuck holding unit 235 through a shaft 236. The shaft 236 and the lower chuck drive unit 237 constitute a moving mechanism in the present disclosure. The lower chuck holding unit 235 is supported by the moving mechanism. The lower chuck 231 can be vertically and horizontally moved by the lower chuck drive unit 237. Moreover, the lower chuck 231 can be rotated about a vertical axis by the lower chuck drive unit 237. Lift pins (not shown) for supporting the lower wafer W_{L} from below and moving the lower wafer W_{L} up and down are installed below the lower chuck holding unit 235. The lift pins are inserted into the below-mentioned through-holes 277 formed in the lower chuck 231 (the lower chuck holding unit 235) and can protrude from the upper surface of the lower chuck 231.

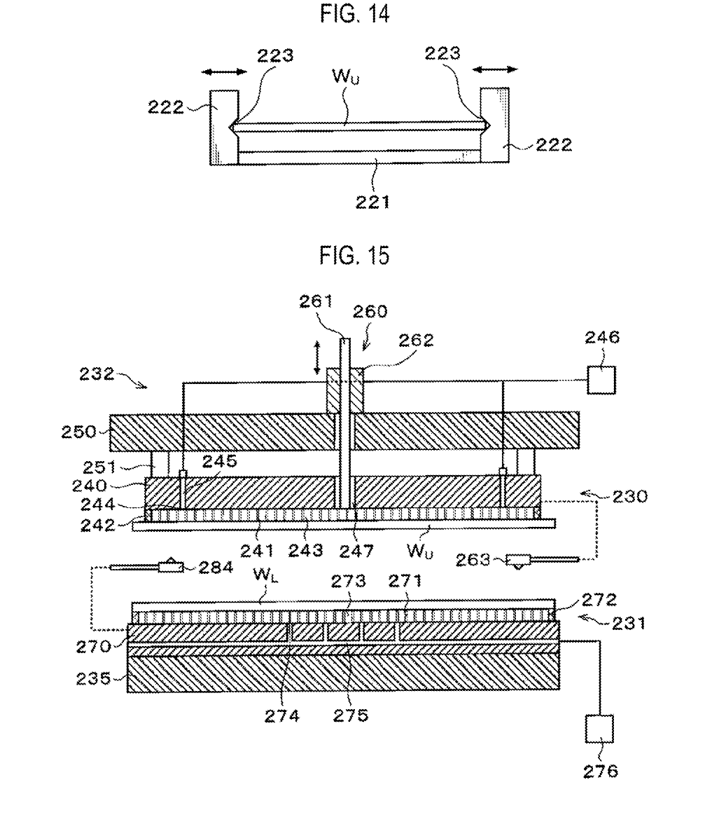

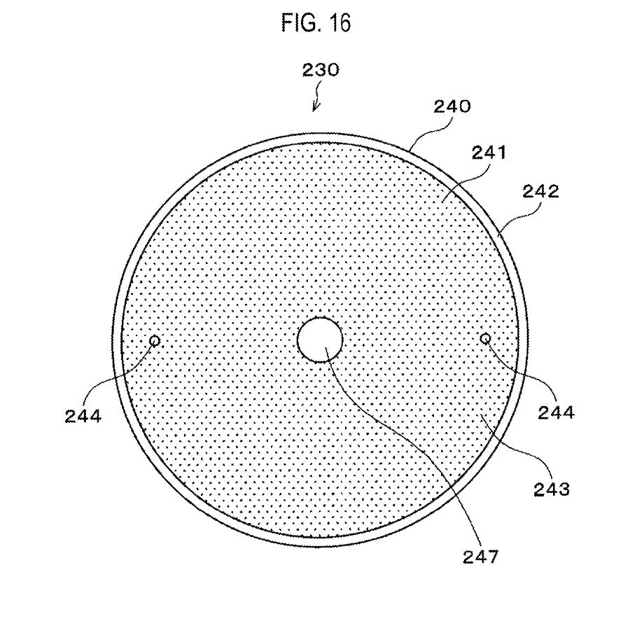

As shown in FIGS. 15 and 16, the upper chuck 230 employs a pin chuck method. The upper chuck 230 includes a body portion 240 having a diameter smaller than the diameter of the upper wafer W_{U} when seen in a plan view. A plurality of pins 241 making contact with the rear surface W_{U2} of the upper wafer W_{U} is installed on the lower surface of the body portion 240. Each of the pins 241 has a diameter of, e.g., 0.1 mm to 1 mm, and a height of, e.g., several ten μm to several hundred μm. The pins 241 are uniformly arranged at an interval of, e.g., 2 mm. An outer wall portion 242 configured to support the outer periphery portion of the rear surface W_{U2} of the upper wafer W_{U} is installed on the lower surface of the body portion 240. The outer wall portion 242 is annularly formed at the outer side of the pins 241. The outer wall portion 242 has a thickness of, e.g., 0.2 mm to 2 mm.

Suction ports 244 for vacuum-sucking the upper wafer W_{U} are formed on the lower surface of the body portion 240 in an inner region of the outer wall portion 242 (hereinafter often referred to as a “suction region 243”). The suction ports 244 are formed, e.g., at two points in the outer periphery portion of the suction region 243. Suction pipes 245 installed inside the body portion 240 are connected to the suction ports 244. A vacuum pump 246 is connected to the suction pipes 245 through a joint.

The suction region 243 surrounded by the upper wafer W_{U}, the body portion 240 and the outer wall portion 242 is vacuum-sucked via the suction ports 244 to be depressurized. At this time, the external atmosphere of the suction region 243 is kept at atmospheric pressure. Therefore, the upper wafer W_{U} is pressed toward the suction region 243 by the atmospheric pressure just as much as the depressurized amount, whereby the upper wafer W_{U} is drawn and held by the upper chuck 230.

In this case, the pins 241 are uniform in height, which makes it possible to reduce the flatness of the lower surface of the upper chuck 230. By making the lower surface of the upper chuck 230 flat (by reducing the flatness of the lower surface of the upper chuck 230) in this manner, it is possible to suppress the vertical distortion of the upper wafer W_{U} held by the upper chuck 230. Since the rear surface W_{U2} of the upper wafer W_{U} is supported by the pins 241, the upper wafer W_{U} is easily separated from the upper chuck 230 upon releasing the vacuum-suction applied to the upper wafer W_{U} by the upper chuck 230.

A through-hole 247 extending through the body portion 240 in the thickness direction thereof is formed in the central area of the body portion 240. The central area of the body portion 240 corresponds to the central portion of the upper wafer W_{U} drawn and held by the upper chuck 230. A pressing pin 261 of a pressing member 260 (which will be described later) is inserted into the through-hole 247.

The aforementioned upper chuck holding unit 232 configured to support the upper chuck 230 includes a support member 250 on which the pressing member 260 to be described later is installed and a position adjusting mechanism 251 installed on the support member 250 and configured to adjust the position of the upper chuck 230 such that a predetermined gap, e.g., a gap of 1 mm in size, is formed between the upper chuck 230 and the support member 250. The position adjusting mechanism 251 suppresses the tilt of the upper chuck 230 and maintains the parallelism of the upper chuck 230.

The pressing member 260 configured to press the central portion of the upper wafer W_{U} is installed on the support member 250. The pressing member 260 has a cylinder structure and includes a pressing pin 261 and an outer tube 262 which serves as a guide during the up/down movement of the pressing pin 261. The pressing pin 261 can be vertically moved through the through-hole 247 by a drive unit (not shown) equipped with, e.g., a motor. During the below-mentioned joining process of the wafers W_{U} and W_{L}, the pressing member 260 can bring the central portion of the upper wafer W_{U} and the central portion of the lower wafer W_{L} into contact with each other and can press them against each other.

An upper image pickup member 263 configured to pick up an image of the front surface W_{L1} of the lower wafer W_{L} is disposed in the upper chuck 230. Examples of the upper image pickup member 263 may include a wide-angle CCD (Charge-Coupled Device) camera. In some embodiments, the upper image pickup member 263 may be disposed above the upper chuck 230.

As shown in FIGS. 15 and 17, the lower chuck 231 employs a pin chuck method just like the upper chuck 230. The lower chuck 231 includes a body portion 270 having a diameter larger than the diameter of the lower wafer W_{L} when seen in a plan view. A plurality of pins 271 making contact with the rear surface W_{L2} of the lower wafer W_{L} is installed on the upper surface of the body portion 270. Each of the pins 271 has a diameter of, e.g., 0 1 mm to 1 mm, and a height of, e.g., several ten μm to several hundred μm. The pins 271 are uniformly arranged at an interval of, e.g., 1 mm. An outer wall portion 272 configured to support the outer periphery portion of the rear surface W_{L2} of the lower wafer W_{L} is installed on the upper surface of the body portion 270. The outer wall portion 272 is annularly formed at the outer side of the pins 271. The outer wall portion 272 has a thickness of, e.g., 0.2 mm to 2 mm.

A plurality of suction ports 274 for vacuum-sucking the lower wafer W_{L} are formed on the upper surface of the body portion 270 in an inner region 273 of the outer wall portion 272 (hereinafter often referred to as a “suction region 273”). Suction pipes 275 installed inside the body portion 270 are connected to the suction ports 274. For example, two suction pipes 275 are installed. A vacuum pump 276 is connected to the suction pipes 275.

The suction region 273 surrounded by the lower wafer W_{L}, the body portion 270 and the outer wall portion 272 is vacuum-sucked from the suction ports 274 to depressurize the suction region 273. At this time, the external atmosphere of the suction region 273 is kept at atmospheric pressure. Therefore, the lower wafer W_{L} is pressed toward the suction region 273 by the atmospheric pressure just as much as the depressurized amount, whereby the lower wafer W_{L} is drawn and held by the lower chuck 231.

In this case, the pins 271 are uniform in height, which makes it possible to reduce the flatness of the upper surface of the lower chuck 231. Since the interval of the adjoining pins 271 is appropriate, it is possible to restrain particles from existing on the upper surface of the lower chuck 231 even if particles exist within the processing vessel 190. By making the upper surface of the lower chuck 231 flat (by reducing the flatness of the upper surface of the lower chuck 231) in this manner, it is possible to suppress the vertical distortion of the lower wafer W_{L} held by the lower chuck 231. Since the rear surface W_{L2} of the lower wafer W_{L} is supported by the pins 271, the lower wafer W_{L} is easily separated from the lower chuck 231 upon releasing the vacuum-suction applied to the lower wafer W_{L} by the lower chuck 231.

Through-holes 277 extending through the body portion 270 in the thickness direction thereof are formed, e.g., at three points, in the vicinity of the center of the body portion 270. Lift pins (not shown) existing below the lower chuck holding unit 235 are inserted into the through-holes 277.

Guide members 280 configured to prevent the wafers W_{U} and W_{L} and the superposed wafer W_{T} from jutting out or sliding down from the lower chuck 231 are installed in the outer periphery portion of the body portion 270. The guide members 280 are provided at a plurality of points, e.g., four points, in the outer periphery portion of the body portion 270.

As shown in FIG. 15, a lower image pickup member 281 configured to pick up an image of the front surface W_{U1} of the upper wafer W_{U} is disposed in the lower chuck 231. Examples of the lower image pickup member 281 may include a wide-angle CCD (Charge-Coupled Device) camera. In some embodiments, the lower image pickup member 281 may be disposed above the lower chuck 231.

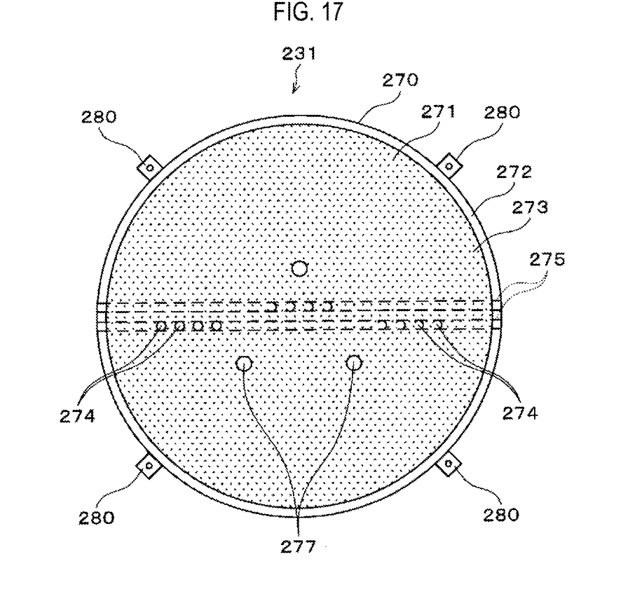

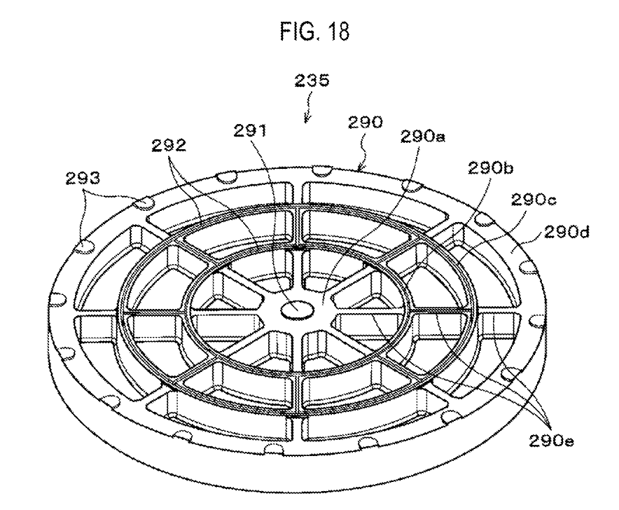

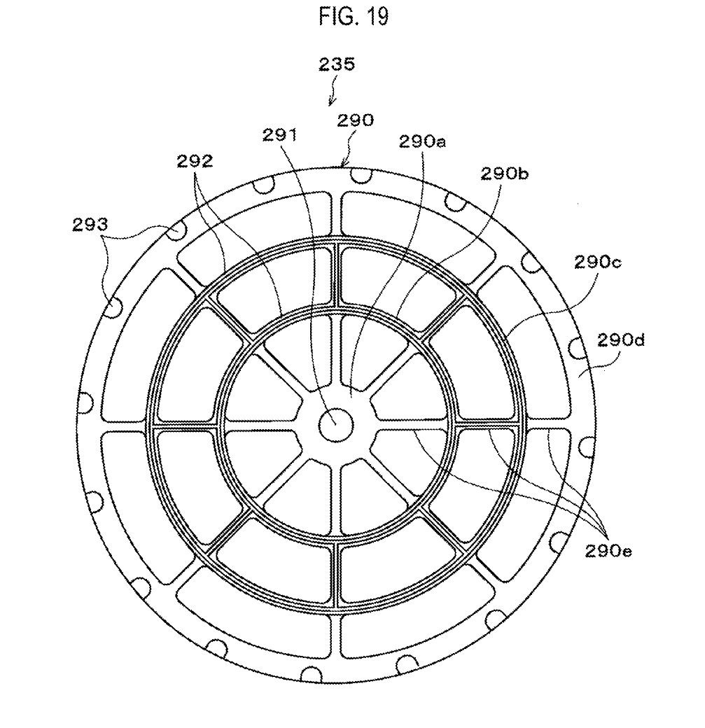

The lower chuck holding unit 235 for holding the lower chuck 231 is configured to draw and hold the lower chuck 231 by vacuum-sucking the lower chuck 231. As shown in FIGS. 18 and 19, the lower chuck holding unit 235 includes a body portion 290 having the same diameter as the lower chuck 231 when seen in a plan view. In the present embodiment, for the sake of reducing the weight of the body portion 290, the interior of the body portion 290 is cut away such that a plurality of cavities exist within the body portion 290. More specifically, the body portion 290 is divided into first to fourth body sections 290a, 290b, 290c and 290d. The first body section 290a has a substantially circular shape when seen in a plan view. The second body section 290b, the third body section 290c and the fourth body section 290d are annularly provided in a concentric relationship with the first body section 290a and are arranged in the named order from the first body section 290a toward the outer side. The body sections 290a, 290b, 290c and 290d are connected by a plurality of connecting sections 290e. Remaining sections of the body portion 290 other than the body sections 290a, 290b, 290c and 290d and the connecting sections 290e are hollow.

A central protrusion 291 protruding more than a surrounding section thereof is provided in the central portion of the upper surface of the first body section 290a. The central protrusion 291 makes contact with the rear surface of the lower chuck 231 when the lower chuck holding unit 235 holds the lower chuck 231.

The second body section 290b and the third body section 290c protrude more than the remaining sections of the body portion 290. The second body section 290b and the third body section 290c make contact with the rear surface of the lower chuck 231 when the lower chuck holding unit 235 holds the lower chuck 231. Suction grooves 292 configured to vacuum-suck the lower chuck 231 are formed on the upper surface of the second body section 290b and the upper surface of the third body section 290c. The suction grooves 292 are formed into an annular shape and are concentrically provided in a twofold structure at mutually-differing diameters. A suction pipe (not shown) located within the body portion 290 is connected to the suction grooves 292. A vacuum pump (not shown) is connected to the suction pipe.

In the illustrated example, the connecting sections 290e that interconnect the second body section 290b and the third body section 290c are also formed to protrude just like the second body section 290b and the third body section 290c. Suction grooves 292 are formed on the connecting sections 290e that interconnect the second body section 290b and the third body section 290c. However, the protrusion of the connecting sections 290e and the formation of the suction grooves 292 are not absolutely necessary.

A plurality of peripheral protrusions 293 protruding more than surrounding sections thereof is formed in the outer periphery portion of the upper surface of the fourth body section 290d. The peripheral protrusions 293 are provided at a regular interval in the outer periphery portion of the upper surface of the fourth body section 290d. The peripheral protrusions 293 make contact with the rear surface of the lower chuck 231 when the lower chuck holding unit 235 holds the lower chuck 231.

The lower chuck holding unit 235 configured as above draws and holds the lower chuck 231 by performing vacuum suction from the suction grooves 292 in a state that the central protrusion 291, the second body section 290b, the third body section 290c and the peripheral protrusions 293 make contact with the lower chuck 231. Since the lower chuck holding unit 235 vacuum-sucks, draws and holds the lower chuck 231 in this manner, it is possible to suppress the vertical distortion of the lower chuck 231 and to reduce the flatness of the upper surface of the lower chuck 231.

The body portion 290 may be provided with a positioning pin (not shown) for fixing the horizontal position of the lower chuck 231.

As shown in FIG. 1, the joining system 1 includes the control unit 300. The control unit 300 is, for example, a computer and includes a program storage unit (not shown). The program storage unit stores a program which controls the processing of the wafers W_{U} and W_{L} and the superposed wafer W_{T} performed in the joining system 1. The program storage unit also stores a program which controls the operation of a driving system including the above-described processing units and the transfer units to implement a below-mentioned joining process in the joining system 1. The programs are stored in a computer readable storage medium H such as a hard disk (HD), a flexible disk (FD), a compact disk (CD), a magneto-optical disk (MO), a memory card or the like and may be installed in the control unit 300 by downloading them from the computer readable storage medium H.

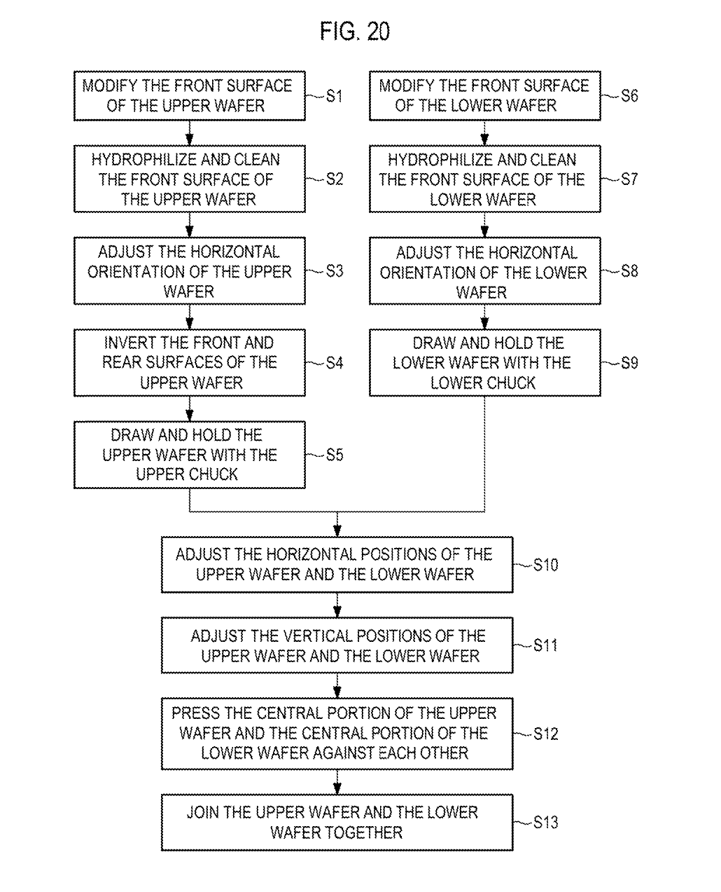

Next, a method of joining the wafers W_{U} and W_{L} using the joining system 1 configured as indicated above will be described. FIG. 20 is a flowchart showing main operations of the wafer joining process.

First, the cassette C_{U} with a plurality of upper wafers W_{U}, a cassette C_{L} with a plurality of lower wafers W_{L}, and an empty cassette C_{T} are mounted on a specified cassette mounting board 11 of the carry-in/carry-out station 2. Thereafter, the upper wafer W_{U} within the cassette C_{U} is taken out by the wafer transfer unit 22 and is transferred to the transition unit 50 of the third processing block G3 of the processing station 3.

Subsequently, the upper wafer W_{U} is transferred to the surface modification device 30 of the first processing block G1 by the wafer transfer unit 61. The upper wafer W_{U} transferred to the surface modification device 30 is delivered to and mounted on the upper surface of the mounting table 110 by the wafer transfer unit 61. Thereafter, the wafer transfer unit 61 is retracted from the surface modification device 30 and the gate valve 102 is closed. The upper wafer W_{U} mounted on the mounting table 110 is maintained at a predetermined temperature, e.g., 25 degree C. to 30 degree C. by the temperature adjusting mechanism 112.

Thereafter, the suction unit 104 is operated to depressurize the internal atmosphere of the processing vessel 100 to a predetermined vacuum degree, e.g., 67 Pa to 333 Pa (0.5 Torr to 2.5 Torr) through the suction port 103. Then, the internal atmosphere of the processing vessel 100 is kept at the predetermined vacuum degree during the below-mentioned processing of the upper wafer W_{U}.

Thereafter, an oxygen gas is supplied from the gas supply pipe 130 toward the plasma generation region R1 defined within the processing vessel 100. Microwaves of, e.g., 2.45 GHz, are irradiated from the radial line slot antenna 120 toward the plasma generation region R1. Due to the irradiation of the microwaves, the oxygen gas existing within the plasma generation region R1 is excited into plasma. For example, the oxygen gas is ionized. At this time, the microwaves moving downward are reflected by the ion passing structural body 140 to stay within the plasma generation region R1. As a result, high-density plasma is generated within the plasma generation region R1.

Subsequently, a predetermined voltage is applied to the electrodes 141 and 142 of the ion passing structural body 140 by the power supply 145. Thus, only the oxygen ions generated in the plasma generation region R1 are introduced by the electrodes 141 and 142 into the processing region R2 through the openings 144 of the ion passing structural body 140.

At this time, the voltage applied to between the electrodes 141 and 142 is controlled by the control unit 300 to thereby control the energy given to the oxygen ions which pass through the electrodes 141 and 142. The energy given to the oxygen ions is set high enough to cut the double bonds of SiO₂ of the front surface W_{U1} of the upper wafer W_{U} to obtain SiO having a single bond, but small enough not to cause damage in the front surface W_{U1}.

At this time, the current value of an electric current flowing between the electrodes 141 and 142 is measured by the ammeter 146. The amount of the oxygen ions passing through the ion passing structural body 140 can be grasped based on the current value thus measured. Pursuant to the passing amount of the oxygen ions thus grasped, the control unit 300 controls different parameters, such as the amount of the oxygen gas supplied from the gas supply pipe 130, the voltage applied to between the electrodes 141 and 142, and the like, so that the passing amount of the oxygen ions can become a predetermined value.

Thereafter, the oxygen ions introduced into the processing region R2 are irradiated on and implanted into the front surface W_{U1} of the upper wafer W_{U} mounted on the mounting table 110. By the oxygen ions thus irradiated, the double bonds of SiO₂ of the front surface W_{U1} of the upper wafer W_{U} are cut to obtain SiO having a single bond. Since the oxygen ions are used in modifying the front surface W_{U1}, the oxygen ions irradiated on the front surface W_{U1} of the upper wafer W_{U} themselves make contribution to the bonding of SiO. In this way, the front surface W_{U1} of the upper wafer W_{U} is modified (Operation Si in FIG. 20).

At this time, the ion ammeter 111 measures the current value of an ion current generated by the oxygen ions irradiated on the front surface W_{U1} of the upper wafer W_{U}. The irradiation amount of the oxygen ions irradiated on the front surface W_{U1} of the upper wafer W_{U} can be grasped based on the current value thus measured. Pursuant to the irradiation amount of the oxygen ions thus grasped, the control unit 300 controls different parameters, such as the amount of the oxygen gas supplied from the gas supply pipe 130, the voltage applied to between the electrodes 141 and 142, and the like, so that the irradiation amount of the oxygen ions can become a predetermined value.

Then, the upper wafer W_{U} is transferred to the surface hydrophilization device 40 of the second processing block G2 by the wafer transfer unit 61. The upper wafer W_{U} transferred to the surface hydrophilization device 40 is delivered from the wafer transfer unit 61 to the spin chuck 160 and are drawn and held by the spin chuck 160.

Subsequently, the pure water nozzle 173 of the standby section 175 is moved to above the central portion of the upper wafer W_{U} by the nozzle arm 171. The scrub cleaning tool 180 is moved to above the upper wafer W_{U} by the scrub arm 172. Thereafter, pure water is supplied from the pure water nozzle 173 onto the upper wafer W_{U} while rotating the upper wafer W_{U} by the spin chuck 160. Thus, hydroxyl groups (silanol groups) adhere to the front surface W_{U1} of the upper wafer W_{U} modified by the surface modification device 30, whereby the front surface W_{U1} is hydrophilized. The front surface W_{U1} of the upper wafer W_{U} is cleaned by the scrub cleaning tool 180 and the pure water supplied from the pure water nozzle 173 (Operation S2 in FIG. 20).

Next, the upper wafer W_{U} is transferred to the joining device 41 of the second processing block G2 by the wafer transfer unit 61. In the joining device 41, the upper wafer W_{U} is transferred to the position adjusting mechanism 210 by the transfer mechanism 201 via the transition 200. Then, the horizontal orientation of the upper wafer W_{U} is adjusted by the position adjusting mechanism 210 (Operation S3 in FIG. 20).

Thereafter, the upper wafer W_{U} is transferred from the position adjusting mechanism 210 to the holder arm 221 of the inverting mechanism 220. Subsequently, in the transfer region T1, the holder arm 221 is inverted such that the front and rear surfaces of the upper wafer W_{U} are turned upside down (Operation S4 in FIG. 20). That is, the front surface W_{U1} of the upper wafer W_{U} is oriented downward.

Subsequently, the holder arm 221 of the inverting mechanism 220 is rotated about the first drive unit 224 and is moved below the upper chuck 230. Then, the upper wafer W_{U} is transferred from the inverting mechanism 220 to the upper chuck 230. The rear surface W_{U2} of the upper wafer W_{U} is drawn and held by the upper chuck 230 (Operation S5 in FIG. 20). More specifically, the vacuum pump 246 is operated to vacuum-suck the suction region 243 from the suction ports 244, whereby the upper wafer W_{U} is drawn and held by the upper chuck 230. At this time, the lower surface of the upper chuck 230 is kept flat. It is therefore possible to suppress the vertical distortion of the upper wafer W_{U} held by the upper chuck 230. The upper wafer W_{U} waits in the upper chuck 230 until the below-mentioned lower wafer W_{L} is transferred to the joining device 41.

While Operations S1 to S5 described above are being performed with respect to the upper wafer W_{U}, the lower wafer W_{L} is processed following the processing of the upper wafer W_{U}. First, the lower wafer W_{L} is taken out of the cassette C_{L} by the wafer transfer unit 22 and is transferred to the transition unit 50 of the processing station 3.

Subsequently, the lower wafer W_{L} is transferred by the wafer transfer unit 61 to the surface modification device 30 where the front surface W_{L1} of the lower wafer W_{L} is modified (Operation S6 in FIG. 20). The modification for the front surface W_{L1} of the lower wafer W_{L} to be performed in Operation S6 is the same as that performed in Operation S1.

Thereafter, the lower wafer W_{L} is transferred by the wafer transfer unit 61 to the surface hydrophilization device 40 where the front surface W_{L1} of the lower wafer W_{L} is hydrophilized and cleaned (Operation S7 in FIG. 20). The hydrophilizing and cleaning operations for the front surface W_{L1} of the lower wafer W_{L} to be performed in Operation S7 are the same as those performed in Operation S2 and, therefore, will not be described in detail.

Thereafter, the lower wafer W_{L} is transferred to the joining device 41 by the wafer transfer unit 61. In the joining device 41, the lower wafer W_{L} is transferred to the position adjusting mechanism 210 by the wafer transfer mechanism 201 via the transition 200. In the position adjusting mechanism 210, the horizontal orientation of the lower wafer W_{L} is adjusted (Operation S8 in FIG. 20).

Thereafter, the lower wafer W_{L} is transferred by the wafer transfer mechanism 201 to the lower chuck 231 and is drawn and held by the lower chuck 231 (Operation S9 in FIG. 20). More specifically, the vacuum pump 276 is operated to vacuum-suck the suction region 273 from the suction ports 274, whereby the lower wafer W_{L} is drawn and held by the lower chuck 231. Owing to the fact that the lower chuck 231 has a pin chuck structure and further that the lower chuck holding unit 235 draws and holds the lower chuck 231 by vacuum-sucking the same, the vertical distortion of the lower chuck 231 is suppressed and the upper surface of the lower chuck 231 is kept flat. It is therefore possible to suppress the vertical distortion of the lower wafer W_{L} held by the lower chuck 231.

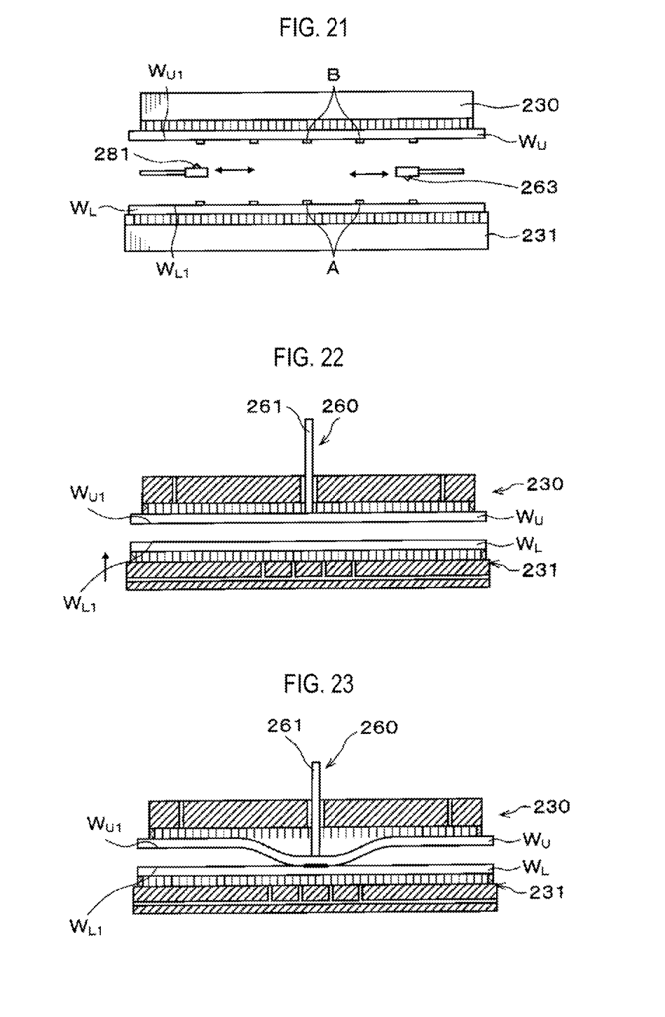

Then, the horizontal positions of the upper wafer W_{U} held by the upper chuck 230 and the lower wafer W_{L} held by the lower chuck 231 are adjusted. As shown in FIG. 21, a plurality of (e.g., four or more) predetermined reference points A are formed on the front surface W_{L1} of the lower wafer W_{L}. Similarly, a plurality of (e.g., four or more) predetermined reference points B are formed on the front surface W_{U1} of the upper wafer W_{U}. Predetermined patterns formed on the wafers W_{U} and W_{L} may be used as the reference points A and B, respectively. Subsequently, the upper image pickup member 263 is horizontally moved to pick up an image of the front surface W_{L1} of the lower wafer W_{L}. Similarly, the lower image pickup member 281 is horizontally moved to pick up an image of the front surface W_{U1} of the upper wafer W_{U}. Thereafter, the horizontal position (including the horizontal orientation) of the lower wafer W_{L} is adjusted by the lower chuck 231 such that the positions of the reference points A of the lower wafer W_{L} indicated on the image picked up by the upper image pickup member 263 coincide with the positions of the reference points B of the upper wafer W_{U} indicated on the image picked up by the lower image pickup member 281. Specifically, the lower chuck 231 is horizontally moved by the lower chuck drive unit 237 to adjust the horizontal position of the lower wafer W_{L}. Thus, the horizontal positions of the upper wafer W_{U} and the lower wafer W_{L} are adjusted (Operation S10 in FIG. 20). The lower chuck 231 may be moved instead of moving the upper image pickup member 263 and the lower image pickup member 281.

In addition, the horizontal orientations of the wafers W_{U} and W_{L} are adjusted by the position adjusting mechanism 210 in Operations S3 and S8. The fine adjustment of the horizontal orientations is performed in Operation S10. In Operation S10 of the present embodiment, the predetermined patterns formed on the wafers W_{U} and W_{L} are used as the reference points A and B. However, other reference points may be used. As an example, the outer peripheral portions and the notch portions of the wafers W_{U} and W_{L} may be used as the reference points.

Thereafter, as shown in FIG. 22, the lower chuck 231 is moved upward by the chuck drive unit 237 to place the lower wafer W_{L} at a predetermined position. At this time, the lower wafer W_{L} is placed such that the gap between the front surface W_{L1} of the lower wafer W_{L} and the front surface W_{U1} of the upper wafer W_{U} becomes equal to a predetermined distance, e.g., 80 μm to 200 μm. In this way, the vertical positions of the upper wafer W_{U} and the lower wafer W_{L} are adjusted (Operation S11 in FIG. 20).

Thereafter, as shown in FIG. 23, the pressing pin 261 of the pressing member 260 is moved downward to thereby lower the upper wafer W_{U} while pressing the central portion of the upper wafer W_{U}. At this time, a load of, e.g., 200 g, which causes the pressing pin 261 to move 70 μm in the absence of upper wafer W_{U} is applied to the pressing pin 261. Then, the pressing member 260 brings the central portion of the upper wafer W_{U} and the central portion of the lower wafer W_{L} into contact with each other and presses them against each other (Operation S12 in FIG. 20). Since a predetermined gap is formed between the upper chuck 230 and the support member 250, it is possible for the gap to absorb the influence of a reaction force when the pressing member 260 presses the upper wafer W_{U}. Inasmuch as the suction ports 244 of the upper chuck 230 are formed in the outer periphery portion of the suction region 243, it is possible for the upper chuck 230 to hold the outer periphery portion of the upper wafer W_{U} even when the pressing member 260 presses the central portion of the upper wafer W_{U}.

Thus, joining begins to occur between the central portions of the upper and lower wafers W_{U} and W_{L} pressed against each other (see a thick line indicated in FIG. 23). Since the front surface W_{U1} of the upper wafer W_{U} and the front surface W_{L1} of the lower wafer W_{L} have been modified in Operations S1 and S6, the Van der Waals force (an intermolecular force) is generated between the front surfaces W_{U1} and W_{L1} so that the front surfaces W_{U1} and W_{L1} are joined together. In addition, since the front surface W_{U1} of the upper wafer W_{U} and the front surface W_{L1} of the lower wafer W_{L} have been hydrophilized in Operations S2 and S7, hydrophilic groups existing between the front surfaces W_{U1} and W_{L1} form hydrogen bonds (by an intermolecular force), which provides a strong bonding of the front surfaces W_{U1} and W_{L1}.

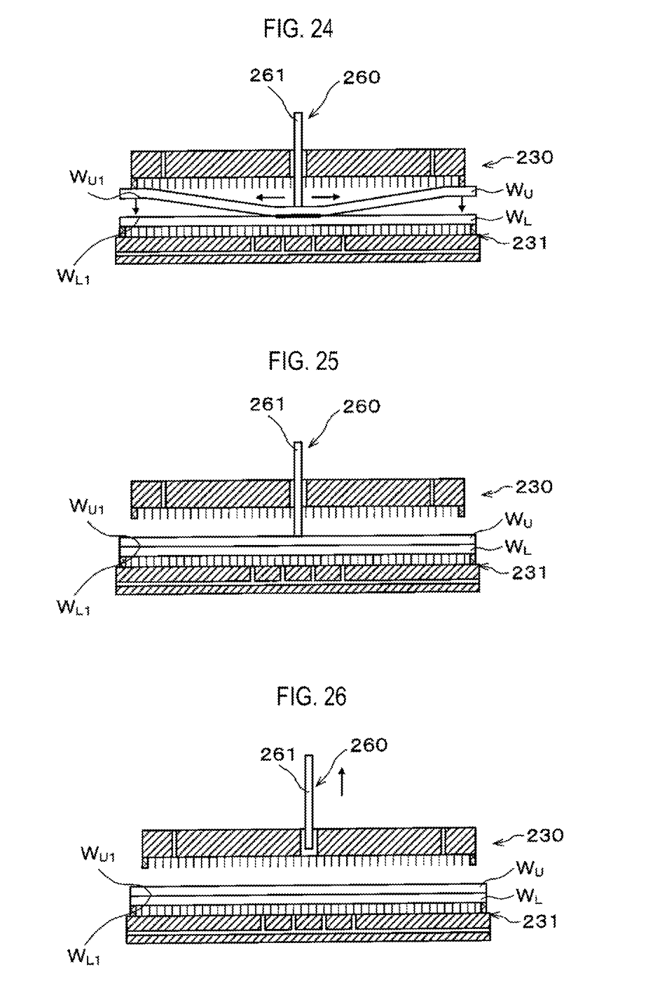

Thereafter, as shown in FIG. 24, the vacuum pump 246 is deactivated to stop the vacuum suction of the upper wafer W_{U} in the suction region 243, in a state that the central portions of the upper and lower wafers W_{U} and W_{L} are pressed by the pressing member 260. This allows the upper wafer W_{U} to be dropped on the lower wafer W_{L}. Since the rear surface W_{U2} of the upper wafer W_{U} is supported by the pins 241, the upper wafer W_{U} is easily separated from the upper chuck 230 upon releasing the vacuum suction of the upper wafer W_{U} performed by the upper chuck 230. Then, the vacuum suction of the upper wafer W_{U} is stopped from the central portion of the upper wafer W_{U} toward the outer periphery portion thereof. The upper wafer W_{U} sequentially drops onto the lower wafer W_{L} and comes into contact with the lower wafer W_{L}, thereby sequentially expanding the joining of the front surfaces W_{U1} and W_{L1} caused by the Van der Waals force and the hydrogen bond. Consequently, as shown in FIG. 25, the front surface W_{U1} of the upper wafer W_{U} and the front surface W_{L1} of the lower wafer W_{L} are brought into contact with each other over the entire area thereof, whereby the upper wafer W_{U} and the lower wafer W_{L} are joined together (Operation S13 in FIG. 20).

Thereafter, as shown in FIG. 26, the pressing pin 261 of the pressing member 260 is moved up to the upper chuck 230. The vacuum pump 246 is deactivated and the vacuum suction of the lower wafer W_{L} in the suction region 273 is stopped, thereby stopping the drawing and holding of the lower wafer W_{L} performed by the lower chuck 231. Since the rear surface W_{L2} of the lower wafer W_{L} is supported by the pins 271, the lower wafer W_{L} is easily separated from the lower chuck 231 upon releasing the vacuum suction of the lower wafer W_{L} performed by the lower chuck 231.

The superposed wafer W_{T} obtained by joining the upper wafer WU and the lower wafer WL is transferred to the transition unit 51 by the wafer transfer unit 61 and is then transferred to the cassette C_{T} of the specified cassette mounting board 11 by the wafer transfer unit 22 of the carry-in/carry-out station 2. In this way, a series of joining processes for the wafers W_{U} and W_{L} is finished.

According to the embodiment described above, the lower chuck holding unit 235 draws and holds the lower chuck 231 by vacuum-sucking the same. It is therefore possible to restrain the lower chuck 231 from being vertically distorted. Accordingly, it is possible to suppress the vertical distortion of the joined superposed wafer W_{T} when joining the upper wafer W_{U} and the lower wafer W_{L} together.

In particular, the suction grooves 292 of the lower chuck holding unit 235 are formed into an annular shape. This enables the lower chuck holding unit 235 to vacuum-suck the lower chuck 231 in the form of a plane, leaving no singular points such as screws or the like employed in the related art. It is therefore possible to further suppress the vertical distortion of the lower chuck 231. Since the suction grooves 292 are formed in a twofold structure in the second body section 290b and the third body section 290c, the lower chuck holding unit 235 can reliably draw and hold the lower chuck 231.

The sections of the lower chuck holding unit 235, which make contact with the lower chuck 231, are limited to the central protrusion 291, the second body section 290b, the third body section 290c and the peripheral protrusions 293. Therefore, as compared with a case where the entire upper surface of the lower chuck holding unit 235 makes contact with the lower chuck 231, it is possible to reduce the contact area. Such reduction of the contact area makes it possible to reduce the bending of the lower chuck 231 and to make the upper surface of the lower chuck 231 flat (or makes it possible to reduce the flatness of the upper surface of the lower chuck 231). Accordingly, it is possible to further reduce the vertical distortion of the lower wafer W_{L} held by the lower chuck 231.

As described above, the lower chuck holding unit 235 makes contact with the lower chuck 231 in the central protrusion 291, the second body section 290b, the third body section 290c and the peripheral protrusions 293. For example, even if particles exist within the processing vessel 190, the particles enter the spaces defined between the lower chuck 231 and the lower chuck holding unit 235. Accordingly, it is possible to further restrain the lower chuck 231 from being vertically distorted by the particles.

The lower chuck holding unit 235 is supported by the shaft 236 and the lower chuck drive unit 237 which constitute the moving mechanism of the lower chuck 231. In this case, even when the lower chuck 231 is moved by the moving mechanism, it is possible for the lower chuck holding unit 235 to appropriately hold the lower chuck 231. Thus, the flatness of the upper surface of the lower chuck 231 can be kept small even after the lower chuck 231 is moved.

In a lower chuck holding unit of the related art, it is often the case that a plurality of parts is vertically stacked and combined. In this case, even if one of the parts has a reduced flatness, the overall flatness becomes larger as the plurality of parts is stacked one above another. As a result, there is a case where the upper surface of the lower chuck holding unit becomes uneven. In the present embodiment, the lower chuck holding unit 235 includes only one body portion 290. It is therefore possible to keep the upper surface of the lower chuck holding unit 235 flat.

If the lower chuck and the lower chuck holding unit are fixed by screws as is the case with the related art, all the screws need to be removed during the maintenance of the lower chuck holding unit. This makes the maintenance cumbersome and onerous. In addition, if the lower chuck holding unit is composed of a plurality of parts, it is necessary to perform maintenance with respect to all the parts. Thus, the maintenance becomes more cumbersome. In the present embodiment, the lower chuck holding unit 235 draws and holds the lower chuck 231. This makes it possible to easily remove the lower chuck holding unit 235 and to readily perform maintenance with respect to the lower chuck holding unit 235. Since the lower chuck holding unit 235 is provided with only one body portion 290, it is possible to more readily perform maintenance.

The joining system 1 includes not only the joining device 41 but also the surface modification device 30 configured to modify the front surfaces W_{U1} and W_{L1} of the wafers W_{U} and W_{L} and the surface hydrophilization device 40 configured to hydrophilize and clean the front surfaces W_{U1} and W_{U}. Thus, the joining of the wafers W_{U} and W_{L} can be efficiently performed within a single system. It is therefore possible to enhance the throughput of the wafer joining process.

In the lower chuck holding unit 235, the configuration of the body portion 290, the configuration of the central protrusion 291, the configuration of the suction grooves 292 and the configuration of the peripheral protrusions 293 are not limited to those of the present embodiment but may be set arbitrarily.

The upper chuck 230 of some embodiments is made as light as possible in order to restrain the upper chuck 230 from being vibrated during the joining of the wafers W_{U} and W_{L}. For example, the upper chuck 230 can be made lightweight by partially cutting the upper surface of the upper chuck 230 and consequently forming grooves.

As described in respect of the foregoing embodiment, it is possible to suppress the vertical distortion of the joined superposed wafer W_{T}. Such a technology of suppressing the vertical distortion is useful in, e.g., CMOS (Complementary Metal Oxide Semiconductor) sensor wafers or BSI (Back Side Illumination) model wafers.

In the aforementioned embodiment, the lower chuck 231 can be moved up and down in the vertical direction and can be moved in the horizontal direction by the lower chuck drive unit 237. Alternatively, the upper chuck 230 may be configured such that it can be moved in the vertical direction. Moreover, the upper chuck 230 and the lower chuck 231 may be configured such that they can be moved up and down in the vertical direction and can be moved in the horizontal direction.

In the joining system 1 of the aforementioned embodiment, the joined superposed wafer W_{T} may be heated to a predetermined temperature after the wafers W_{U} and W_{L} are joined together by the joining device 41. By subjecting the superposed wafer W_{T} to such a heating process, it is possible to firmly couple the joining interfacial surfaces together.

According to the present disclosure, it is possible to suppress a vertical distortion of a joined superposed substrate by appropriately holding substrates when the substrates are joined together.

The present disclosure can be applied to a case where the substrate is not a wafer but other substrate such as a FPD (Flat Panel Display) or a mask reticle for photo masks.

While certain embodiments have been described, these embodiments have been presented by way of example only, and are not intended to limit the scope of the disclosures. Indeed, the novel devices and systems described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A joining device for joining substrates together, comprising:
a first chuck configured to draw and hold a first substrate on a lower surface thereof;
a second chuck provided below the first chuck and configured to draw and hold a second substrate on an upper surface thereof; and
a chuck holding unit provided below the second chuck, the chuck holding unit including an upper surface and suction grooves annularly formed on the upper surface of the chuck holding unit, the suction grooves configured to vacuum-suck the second chuck to draw and hold the second chuck.

2. The device of claim 1, wherein the suction grooves are concentrically provided in a twofold structure at mutually-differing diameters.

3. The device of claim 1, wherein a central protrusion protruding more than a surrounding section thereof and making contact with the second chuck is provided in a central portion of the upper surface of the chuck holding unit, and a plurality of peripheral protrusions protruding more than surrounding sections thereof and making contact with the second chuck is formed in an outer periphery portion of the upper surface of the chuck holding unit.

4. The device of claim 1, wherein the chuck holding unit is supported by a moving mechanism provided below the chuck holding unit, the moving mechanism configured to move the second chuck.

5. A joining system provided with a joining device of claim 1, the joining system comprising:
a processing station including the joining device; and
a carry-in/carry-out station configured to retain the first substrate, the second substrate or a superposed substrate obtained by joining the first substrate and the second substrate together, and configured to carry the first substrate, the second substrate or the superposed substrate into and out of the processing station,
wherein the processing station includes a surface modification device configured to modify a front surface of the first substrate to be joined or a front surface of the second substrate to be joined, a surface hydrophilization device configured to hydrophilize the front surface of the first substrate or the second substrate modified by the surface modification device, and a transfer zone in which the first substrate, the second substrate or the superposed substrate is transferred with respect to the surface modification device, the surface hydrophilization device and the joining device,
wherein the joining device is configured to join the first substrate and the second substrate whose front surfaces are hydrophilized by the surface hydrophilization device.
